(19) United States
(12) Patent Application Publication
(10) Pub. No.: US 2014/0145571 A1
(43) Pub. Date: May 29, 2014

(54) Assembly for Digital Storage Appliance

(71) Applicant: CONNECTED DATA, INC., Santa Clara, CA (US)

(72) Inventors: Brad Lee Morse, Sunnyvale, CA (US); Scott Bowie, Redwood City, CA (US); Parson Wang Yu-Jiun, Taipei (TW); Raymond Oliver, Killucan (IE); Hannah Loh Bing Ngor, Shenzhen (CN); Janette Chong En Teng, Shenzhen (CN); Wong Ze Shen, Shenzhen (CN)

(21) Appl. No.: 13/688,995

(22) Filed: Nov. 29, 2012

(51) Int. Cl. H05K 5/03; H05K 5/02

(52) U.S. Cl. CPC H05K 5/03; H05K 5/0217
USPC 312/223.2

(57) ABSTRACT

A carrier for a disk drive includes a back member configured to abut a face of the disk drive; a pair of side members coupled to the back member, configured to abut opposing sides of the disk drive; and a pair of flexible tangs, each tang coupled to one of the side members and configured to removably mount the carrier in a base. The back member is, or the side members are, or the back member and side members are, configured with a set of attachment mechanisms in locations that correspond to locations, in the disk drive, of screw holes used for mounting so that the disk drive is removably mountable in the carrier using the attachment mechanisms and an assembly of the carrier with the disk drive is removably mountable in the base.

### TECHNICAL FIELD

The present invention relates to digital storage devices, and more particularly to a mechanical assembly for a digital storage appliance.

### BACKGROUND ART

Digital storage appliances are known in the prior art. It is known, for example, to house an external disk drive in a structure distinct from that of a computer to which it is coupled.

### SUMMARY OF THE EMBODIMENTS

In one embodiment, the present invention provides a carrier for a disk drive. The embodiment includes a back member configured to abut a face of the disk drive; a pair of side members coupled to the back member, configured to abut opposing sides of the disk drive; and a pair of flexible tangs, each tang coupled to one of the side members and configured to removably mount the carrier in a base. In this embodiment, the back member is, or the side members are, or the back member and side members are, configured with a set of attachment mechanisms in locations that correspond to locations, in the disk drive, of screw holes used for mounting so that the disk drive is removably mountable in the carrier using the attachment mechanisms and an assembly of the carrier with the disk drive is removably mountable in the base.

In a related embodiment, the attachment mechanisms are screws, placed through holes in the back member, or in the side members, or in the back member and the side members, as the case may be, that are removably insertable into corresponding screw holes in the disk drive. In another related embodiment, the attachment mechanisms are pegs, mounted on the back member, or on the side members, or on the back member and the side members, as the case may be, that are removably insertable into corresponding screw holes in the disk drive.

In a related embodiment, a portion of the back member is configured to engage with a corresponding portion of the base. In a related embodiment, the portion of the back member has a dove-tailed cross section and the portion of the base is configured to receive the dove-tailed cross section of the portion of the back member when the latter is slid into the former. In a related embodiment, each of the tangs is configured for releasably latching the carrier in a base.

In another related embodiment, the set of pegs of the back member includes a set of nibs and a set of pegs, wherein each nib is smaller than each peg. In a related embodiment, the set of pegs of each side member includes a set of nibs and a set of pegs, wherein each nib is smaller than each peg. In a related embodiment, each tang has a notch configured to engage with a corresponding protrusion in the base, so that the tang can be moved inwardly toward the disk drive to release the protrusion from engagement with the notch and wherein the tang is biased in a position wherein the protrusion is normally engaged in the notch.

In yet another related embodiment, the carrier is configured to accommodate a disk drive between 7.0 mm and 15.0 mm in thickness. In a related embodiment, all components thereof are integrally formed from a single piece of material. In a related embodiment, all components are plastic and formed in a mold.

In a related embodiment, the carrier includes a flexible spring that connects the pair of side members, wherein the spring is configured to transfer pressure applied to the spring to the side members.

Another embodiment of the present invention is an assembly for a digital storage appliance. The assembly includes a base comprising a recess with protrusions configured to latch a module that is removably insertable in the base; a disk drive carrier having a back member configured to abut a face of the disk drive; a pair of side members coupled to the back member, configured to abut opposing sides of the disk drive; and a pair of flexible tangs, each tang coupled to one of the side members and configured to removably latch with one of the protrusions in the base so as to removably mount the carrier in the base; and a cover configured to mate with the base to enclose the mounted disk drive carrier. The back member is, or the side members are, or the back member and side members are, configured with a set of attachment mechanisms in locations that correspond to locations, in the disk drive, of screw holes used for mounting so that the disk drive is removably mountable in the carrier using the attachment mechanisms and the module, constituting the carrier with the disk drive, is removably mountable in the base.

In a related embodiment, the protrusions of the base are disposed along opposing sides of the recess. In a related embodiment, a stub of the base comprises a socket with a dove-tailed cross section configured to receive a back member of the disk drive carrier. In a related embodiment, the base further comprises circuitry disposed in the recess that detects a presence of a disk drive inserted into the recess. In a related embodiment, the protrusions are configured to move the latched tangs inward towards the disk drive, thereby further securing a disk drive mounted into the disk drive carrier. In a related embodiment, a height of the disk drive carrier mounted in the base is greater than a height of the cover when mated with the base such that a top inner surface of the cover depresses a spring disposed at the top of the disk drive carrier, thereby further securing the disk drive carrier within the base.

In a related embodiment, the base comprises a first plurality of grooves disposed along an outer perimeter and the cover comprises a first plurality of teeth disposed along an inner perimeter, such that the cover mates with the base by latching the first plurality of teeth with the first plurality of grooves. In a related embodiment, the first plurality of teeth latches with the first plurality of grooves to lock the position of the cover relative to the base. In a related embodiment, the base comprises a second plurality of grooves disposed along the outer perimeter and the cover comprises a second plurality of teeth disposed along the inner perimeter, and wherein the second plurality of teeth latches with the second plurality of grooves to stabilize the position of the cover relative to the base.

In another related embodiment, the present invention provides an assembly for a digital storage appliance. The assembly includes a base comprising a recess to receive a module that is removably insertable in the base; a disk drive carrier having a back member configured to abut a face of the disk drive; a pair of side members coupled to the back member, configured to abut opposing sides of the disk drive; and a cover. The back member is, or the side members are, or the back member and side members are, configured with a set of attachment mechanisms in locations that correspond to locations, in the disk drive, of screw holes used for mounting so that the disk drive is removably mountable in the carrier using the attachment mechanisms and the module, constituting the carrier with the disk drive, is removably mountable in the base. A spring is mounted on the disk drive carrier, and the spring is exposed above the disk drive when the module is mounted in the base. The cover is configured to mate with the base and, when rotated about a vertical axis, to assume a latched position with respect to the base. The cover is also configured, when mated to the base, to enclose the mounted disk drive carrier. The cover has an inner top surface, and, when the carrier is in the latched position, the spring engages against the inner top surface of the cover and applies a force tending to urge the cover upward and away from the base in a manner to assist in maintaining the latched position.

In a related embodiment, the spring is implemented by an arcuate flexible band linking the pair of side members of the carrier.

### BRIEF DESCRIPTION OF THE DRAWINGS

The foregoing features of embodiments will be more readily understood by reference to the following detailed description, taken with reference to the accompanying drawings, in which:

FIG. 1 shows an apparatus with a cover latched to a base;

FIG. 2 shows an apparatus in which the cover has been unlatched from the base, wherein a carrier with a disk drive coupled therein is removably mounted in the base;

FIG. 3 shows a disk drive carrier mounted in the base;

FIG. 4 shows a disk drive carrier;

FIG. 5 shows another exemplary disk drive carrier;

FIG. 6 shows exemplary pegs disposed on the side member and the back member of the disk drive carrier, proximate to a tang;

FIG. 7 shows an exemplary peg disposed on the back member of the disk drive carrier proximate to the spring;

FIG. 8 shows an exemplary peg disposed on the back member of the disk drive carrier proximate to the tang;

FIG. 9 shows exemplary pegs disposed on the side member and the back member of the disk drive carrier, proximate to the spring;

FIG. 10 shows a backside view of the disk drive carrier, including a portion that protrudes from the outer surface of the disk drive carrier;

FIG. 11 shows a disk drive carrier with a disk drive mounted therein;

FIG. 12 shows a base;

FIG. 13 shows an overhead perspective of the base;

FIG. 14 shows a side perspective of the base;

FIG. 15A shows a top perspective of a cover;

FIG. 15B shows a bottom perspective of the cover;

FIG. 16 shows a group of three teeth disposed along an inner perimeter of the cover; and

FIG. 17A shows the cover in an unlatched position relative to the base; and

FIG. 17B shows the cover in a latched position relative to the base.

### DETAILED DESCRIPTION OF SPECIFIC EMBODIMENTS

Definitions. As used in this description and the accompanying claims, the following terms shall have the meanings indicated, unless the context otherwise requires:

A “disk drive” means a non-volatile mass digital storage medium, such as a hard drive or a solid state drive.

A “set” has at least one member.

An “attachment mechanism” configured in the back member or in a side member of a disk drive carrier means a screw placed through a hole in the back member or side member, as the case may be, that is removably insertable into a corresponding screw hole in the disk drive or, alternatively, a peg mounted on the back member or side member, as the case may be, that is removably insertable into a corresponding screw hole in the disk drive.

In general overview, the present disclosure is directed to an assembly with a disk drive carrier (also referred to herein as “carrier”), a base, and a cover. The assembly can be used for distributed file system management. A user can store files, such as word processing documents or photo images, on a disk drive. A user can mount the disk drive in the carrier. As the carrier can accommodate disk drives of different thicknesses, the user can mount any disk drive from a variety of computing devices using the same carrier. Pegs in the carrier can secure the disk drive to the carrier. In typical embodiments, the base contains electronic circuitry that is coupled to the disk drive through a connector. The circuitry may, for example, include electronics configured to cause the disk drive to be seen as a peripheral device that can be coupled to a computer through a USB connector. Alternatively, or in addition, the circuitry is configured to mount the drive on a network. In various embodiments, the network is a wireless network that is compliant with IEEE standards under 802.11x. In such embodiments, the drive may be accessed by computers coupled to the assembly over the wireless network.

The user can mount the carrier into the base. Notches in tangs on the carrier can engage with protrusions in the base to secure the position of the carrier within the base. Further, the width of the recess receiving the carrier can secure the disk drive to the carrier. The user can cover the carrier and base with a cover. The cover can depress the top of the carrier, further securing the carrier's position in the base. Rotating the cover can lock the position of the cover relative to the base, and the enclosure can withstand sudden trauma, such as being dropped or knocked off a table.

When the carrier latches to the base, the base detects the presence of the disk drive. The base communicates with a distributed file system management service on a server. The base can transfer files from the disk drive to the server, or transfer files from the server to the disk drive. Thus, the assembly enables a user to share or receive files while taking few actions.

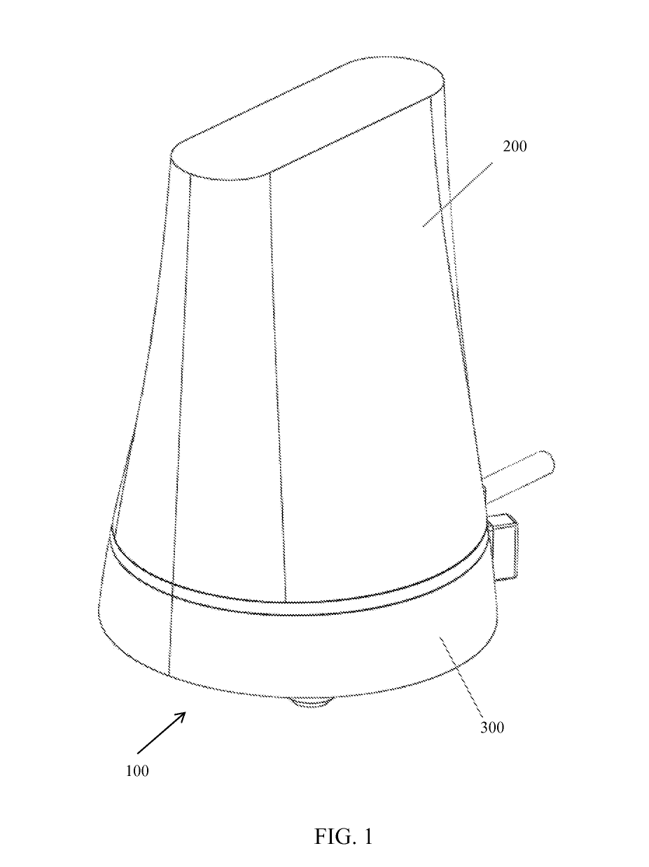

FIG. 1 shows an apparatus 100 (also referred to herein as an assembly) with a cover 200 latched to a base 300. The cover 200 can latch to the base 300 to attain a locked position. In some embodiments, in the locked position, the cover 200 cannot be unlatched from the base 300 by pulling the cover 200 in a direction perpendicular to the base 300. In some embodiments, in the locked position, the cover 200 and base 300 can remain latched despite sudden trauma to the assembly 100, e.g., the assembly 100 is knocked off a table or dropped. In some embodiments, when the base 300 detects that the cover 200 has latched, the base 300 can illuminate a light ring to indicate that the connection has been made. For example, the base 300 can power light emitting diodes (LEDs) disposed within a light ring.

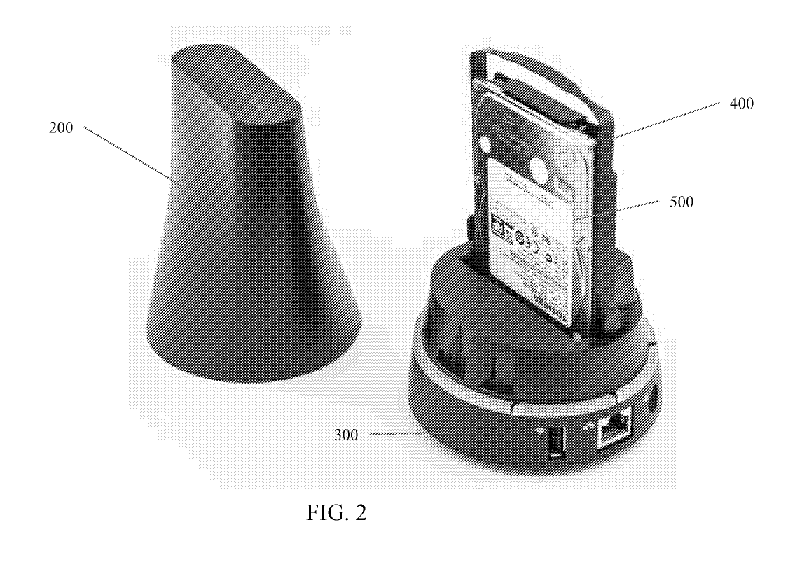

FIG. 2 shows an apparatus 100 in which the cover 200 has been unlatched from the base 400, wherein a carrier 400 with a disk drive 500 coupled therein is removably mounted in the base 300. In some embodiments, rotating the cover 200 can latch the cover 200 to or unlatch the cover 200 from the base 300. For example, when the cover 200 is disposed over the base 300, rotating the cover 200 about 6° in a clockwise direction can latch the cover 200 thereto. Rotating the cover 200 about 6° in a counter-clockwise direction can unlatch the cover 200 from the base 300. In various embodiments, the cover 200 can be rotated different degrees with respect to the base 300 to latch or unlatch. In the unlatched position, the cover 200 can be removed from the base 300 by pulling the cover 200 in a direction perpendicular to the base 300.

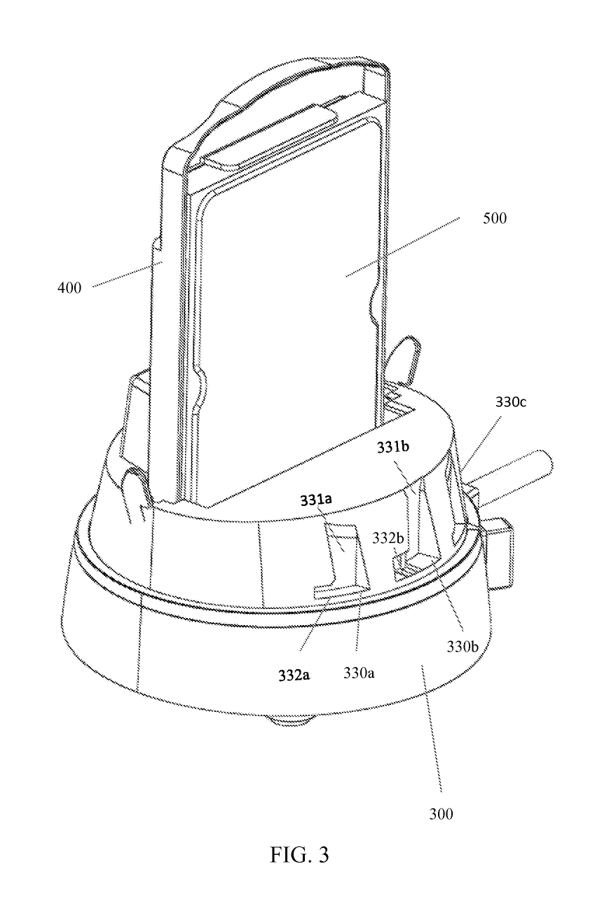

FIG. 3 shows a disk drive carrier 400 mounted in the base 300. To mount the carrier 400 in the base 300, the carrier 400 can be inserted into a recess in the base 300, as described in more detail below. Notches in the tangs of the carrier 400 can engage with protrusions in the base 300, as described in more detail below. The base 300 can accommodate disk drives of different thicknesses. In some embodiments, the maximum thickness of a disk drive that the base 300 can accommodate can depend on the width of the recess. For example, in embodiments where the recess in the base 300 is about 15.00 mm wide, the maximum thickness of a disk drive that can fit in the support 300 is about 15.00 mm.

In some embodiments, the base 300 can accommodate disk drives of different thicknesses. In some embodiments, the base 300 can accommodate a disk drive that is about 7.0 mm thick. In some embodiments, the base 300 can accommodate a disk drive that is about 15.0 mm thick. The base 300 can accommodate disk drives with thicknesses, for example, ranging from about 7.0 mm through about 15.0 mm. Further, many disk drives of different thicknesses have screw holes in the same positions. Since attachment mechanisms 435 are positioned on the carrier 400 to engage screw holes of such disk drives 500, the carrier 400 can accommodate various disk drives regardless of their thicknesses. Thus, the same base 300 can be used with disk drives of different storage capacities and form factors that are used for different types of computing devices. In some embodiments, the thickness of the disk drive accommodated by the base 300 is limited by the width of the recess 305 in the base 300 that receives the carrier 400 and disk drive 500.

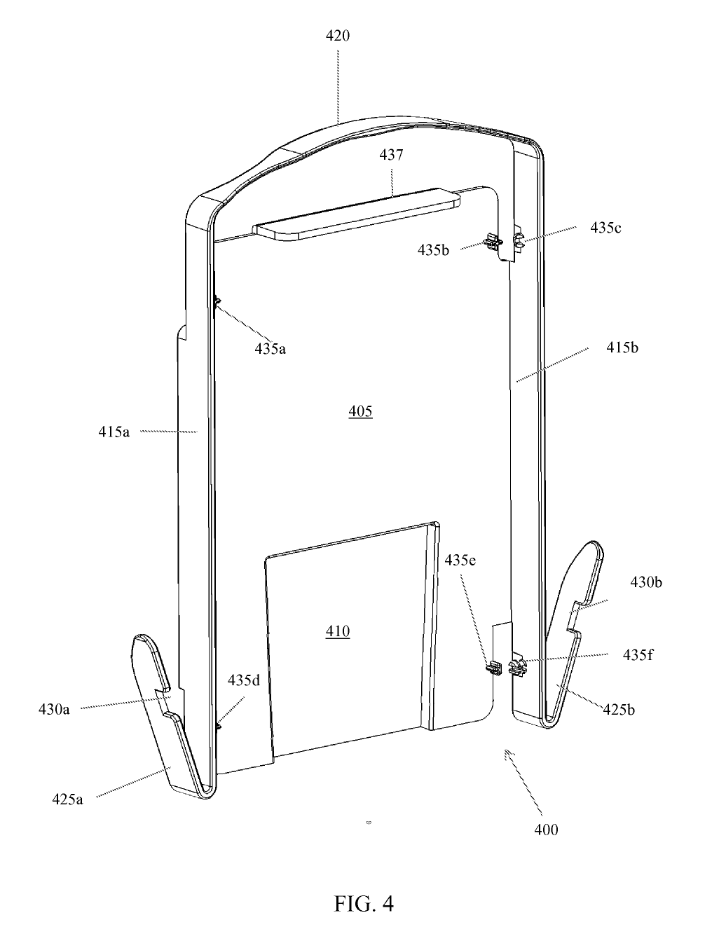

FIG. 4 shows an exemplary carrier 400. The carrier 400 includes a back member 405 with an inner surface and outer surface (not shown). The back member 405 includes a portion 410 that protrudes from the outer surface. The portion 410 can be shaped like a parallelogram or a trapezoid, although the portion 410 can be manufactured into other shapes, as would be appreciated by one of ordinary skill in the art. In some embodiments, the cross section of the portion 410 is a dovetail. The portion 410 can be configured to be inserted into a socket in a stub of the base 300 to form a sliding dovetail connection, as described in more detail below.

The carrier 400 includes a pair of side members 415a, 415b (collectively, “415”) that are coupled to the back member 405. The side members 415 are coupled to a spring 420 disposed at the top of the carrier 400. In this embodiment, the spring 420 is implemented as an arcuate band linking the side members 415a and 415b. The spring 420 can be used for carrying the carrier 400, e.g., transporting the carrier or extracting the carrier from a base. In some embodiments, the spring 420 can be shaped to have curvature. The spring 420 can be flexible. When pressure is applied to the spring 420, the spring 420 can absorb pressure and propagate at least a portion of the pressure through the side members 415.

Each side member 415 is coupled to a tang 425a, 425b (collectively, “425”). The distal end of a side member 415 can be coupled to a distal end of a tang 425. The tang 425 can be positioned to form an acute angle with the side member 415. The tangs 425 can be flexible. A user can move the tangs 425 inward towards the side members 415, thereby modifying the overall width of the carrier 400. Such modification can enable the carrier 400 to fit into the recess of the base 300. The tangs 425 can absorb tension from the user and propagate at least a portion of the tension through the side members 415.

The tangs 425 can each include a notch 430a, 430b (collectively, “430”). The notches 430 of the tangs 425 can be configured to engage with protrusions in a base 300 to latch the carrier 400 to the support 300. A user can move the tangs 425 inward towards the side members 415, insert the carrier 400 into a recess in a base 300, and release the tangs 425. Upon the release, the tangs 425 can move outward from the side members 415 to engage with the protrusions. When the user wishes to remove the carrier 400 from the base, the user can move the tangs 425 inward towards the side members 415 to disengage the notches 430 from protrusions in the base 300. Then, the user can pull the carrier 400 out of the recess.

The carrier 400 can include pegs 435a, 435b, 435c . . . (collectively, “435”) for removably mounting a disk drive 500 therein. The pegs 435 can be disposed on the carrier 400 in locations that correspond to the locations of screwholes on a disk drive 500. Although the carrier 400 includes at least one peg 435 in a location corresponding to the location of a screwhole, the carrier 400 can have fewer pegs 435 than the total number of screwholes for a disk drive (e.g., not all the screwholes on a disk drive need to be coupled to the carrier 400). At least some of the pegs 435 can be disposed on the back member 405. At least some of the pegs 435 can be disposed on the side members 415. In some embodiments, all the pegs 435 are the same size. In some embodiments, the pegs 435 can be different sizes. For example, pegs 435 disposed on the back member 405 and side members 415 proximate to the spring 420 can be smaller than pegs 435 disposed proximate to the tangs 425. In these embodiments, the pegs 435 disposed on the back member 405 and side members 415 proximate to the spring 420 can be referred to as nibs.

In some embodiments, all the pegs 435 can have the same shape. In some embodiments, the pegs 435 can have different shapes. In some examples, pegs 435 disposed proximate to the spring 420 can have different shapes from pegs 435 disposed proximate to the tangs 425. In some examples, pegs 435 disposed on the back member 405 can have different shapes from pegs 435 disposed on the side members 415. In some embodiments, pegs 435 can have cross rib heads.

In some embodiments, the pegs 435 can be integrally formed as part of the carrier 400. The carrier 400 can be formed from an integral piece of material that has been shaped to include the pegs. In some embodiments, the pegs 435 can be separated from the back member 405, the side members 415, or both. The pegs 435 can be components inserted into sockets in the carrier 400, wherein the sockets are positioned in locations that correspond to the locations of screwholes on a disk drive 500. In these embodiments, individual pegs 435 can be removed and replaced, due to wear and tear or breakage, without discarding the entire carrier 400.

In some embodiments, the sockets can be recesses within the carrier 400. A peg 435 inserted into a recess can be retained therein due to the fit between the cross sectional areas of the peg 435 and recess, as well as the contact between an end of the peg 435 and a portion of the back member 405 or side member 415 of the carrier 400. In some embodiments, the sockets can be holes within the carrier 400. A peg 435 inserted into a hole can be retained therein due to the fit between the cross sectional areas of the peg 435 and hole.

In various embodiments, the pegs 435 can be made of the same material as the carrier 400. In various embodiments, either the pegs 435, the carrier 400, or both are made of formed sheet metal, cast metal, cast ceramic, cast glass, three-dimensional (3D) printed ceramic, 3D printed metal, 3D printed plastic, injection-molded plastic, or any combination thereof. Although we have described use of pegs, it will be readily apparent that in lieu, conventional machine screws can be used, and inserted through holes in the carrier located in positions where pegs have been shown in the accompanying drawings. Because screws are more secure, albeit more complex to implement, screws may be provided solely, for example, in the back member or solely in the side members. Alternatively, they may be used in the back member together with the side members.

To mount a disk drive in the carrier 400, a user can position a disk drive 500 against the back member 405 of the carrier 400. The user can align the disk drive's 500 screwholes with the pegs 435 of the carrier 400. In some embodiments, the user can align a top surface of the disk drive 500 with a positioner 437 coupled to the back member 405. The user can apply pressure on the disk drive 500 to insert the pegs 435 disposed on the carrier's back member 405 into the screwholes on the back surface of the disk drive 500. In some embodiments, the pegs 435 can snap into the screwholes. Because the tangs 425 can be flexible, the user can manipulate each tang 425 to align its pegs 435 with the screwholes disposed on the side of the disk drive 500, and then apply pressure to insert the pegs 435 into the screwholes. Thus, the disk drive 500 can be coupled to the carrier 400.

In some embodiments, the side members 415 of the carrier 400, the back member 405, or both are flexible. To remove the disk drive 500 from the carrier 400, a user can bend the side members 415 outward from the disk drive 500 to separate the pegs 435 from the screwholes. Then, the user can pull the back member 405 away from the disk drive 500 to disengage the pegs 435 disposed on the back member 405 from the corresponding screwholes.

In some embodiments, the carrier 400 can be integrally formed from a single piece of material. For example, the carrier 400 can be formed by injection molding. A liquified material can be forced into a mold cavity with the shape of the carrier 400, thereby conforming to the shape of the cavity. As the material cools, the material hardens to form the carrier 400. Exemplary materials include plastic, elastomer, metal, or any other material as would be appreciate by one of ordinary skill in the art.

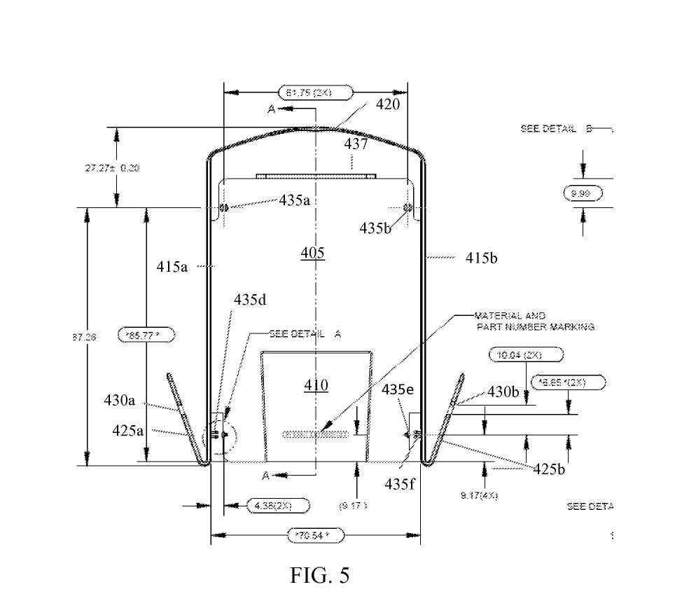

FIG. 5 shows another exemplary carrier 400′. In this embodiment, the carrier includes pegs 435 disposed on the back member proximate to the spring 420, pegs 435 disposed on the back member proximate to the tangs 425, and pegs disposed on the side members 415 proximate to the tangs 425. In this embodiment, the length of the carrier 400 between the top of the spring 420 and the pegs 435 disposed on the back member proximate to the spring 420 can be about 27.27 mm. The length of the carrier 400 between the pegs 435 disposed on the back member proximate to the spring 420 and the distal ends of the side members 415 can be about 87.26 mm. The length of the carrier 400 between the distal end of the back member 405 and the distal end of the side members 415 can be about 1.5 mm.

The width of the back member 405, i.e., the distance between the side members 415, can be about 70.54 mm. In some embodiments, the width between pegs 435 disposed on the back member 405 proximate to the spring 420 can be about 61.75 mm. In some embodiments, the pegs 435 disposed on the back member 405 proximate to the spring 420 can be located about 10.0 mm away from the positioner 437, which aligns with one of the edges of the disk drive 500. In some embodiments, the distance between pegs 435 disposed on the back member 405 proximate to the spring and pegs 435 disposed on the back member 405 proximate to the tang 415 can be about 76.6 mm. In some embodiments, the height of the portion 410 that protrudes from the outer surface of the carrier 400 can be about 38.21 mm. The width of the portion 410 at the top end can be about 41.19 mm. The width of the portion 410 at the bottom end can be about 37.48 mm.

In some embodiments, a side member 415 and a tang 425 can be coupled to form about a 20° angle.

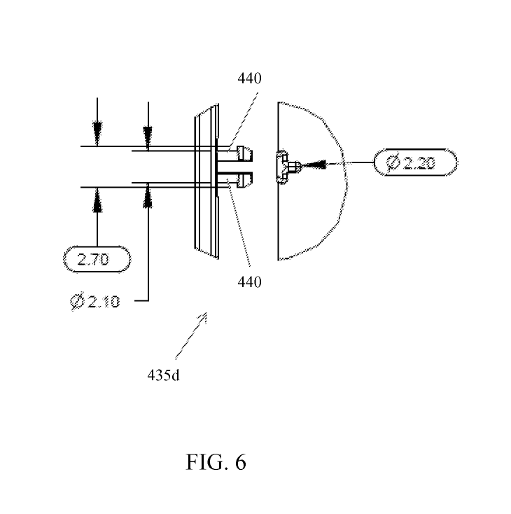

FIG. 6 provides detail of the exemplary peg 435d, of FIG. 5, disposed on the side member 415a proximate to a tang 425a. (Detail of exemplary peg 435f disposed on the side member 415b is similar.) In this embodiment, the peg 435d is implemented by a pair of flexible spaced apart prongs 440, having slightly enlarged heads, so that the prongs can be temporarily bent towards each other for insertion into a corresponding screwhole in the disk drive 500. Once the prongs have entered the screwhole, they exert an outward spring force against the wall of the screw hole, and the heads of the prongs 440 are shaped to engage with the screw threads within the screwhole. Such engagement provides increased resistance against removal of the peg 435d from the screwhole.

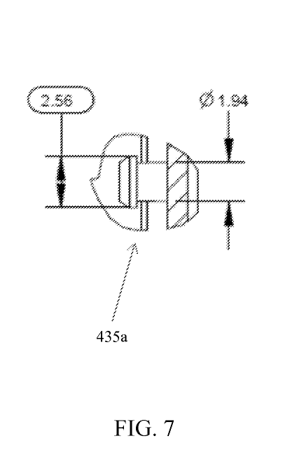

FIG. 7 shows the exemplary peg 435a, of FIG. 5, disposed on the back member 405 of the carrier 400 proximate to the spring 420. (Detail of peg 435b is similar.) In this embodiment, the head of the peg 435a has an extended top that includes a chamfer. In some embodiments, the chamfer can be small. When the peg 435a is inserted in a screw hole, the chamfer is inserted beyond the screw threads of the screw hole. A leading edge of the chamfer then engages at least one of the screw threads. Such engagement provides increased resistance against removal of the peg 435a from the screwhole.

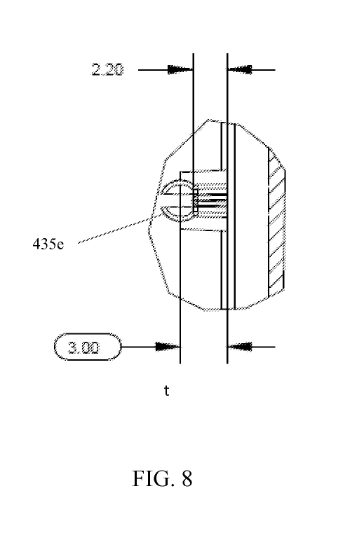

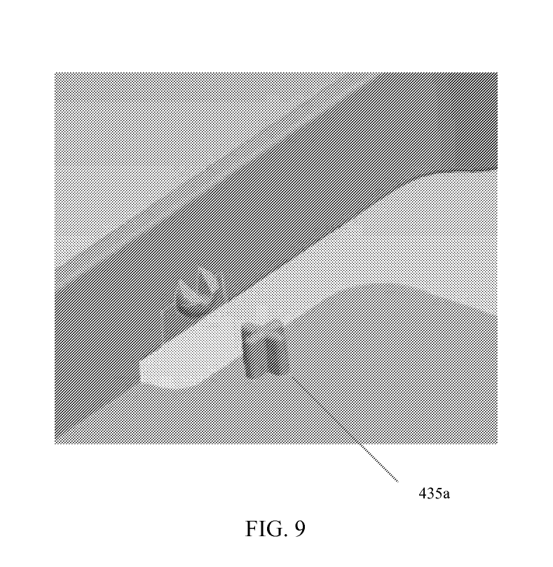

FIG. 8 shows the exemplary peg 435e, of FIG. 5, disposed on the back member 405 of the carrier 400 proximate to the tang 425b shown on the right. (Detail of a corresponding peg proximate to tang 425a shown on left is similar.) The peg 435e is truncated compared to the peg 435a to facilitate insertion of the drive into the carrier 400 and provides an orientation for a corresponding screw hole in the drive. FIG. 9 shows exemplary peg 435g disposed on the side member 415 and exemplary peg 435a disposed on the back member 405 of the carrier 400, proximate to the spring 425. In this embodiment, a peg 435a engages a screw hole positioned on a back surface of a disk drive 500 while another peg 435g, which is truncated to facilitate insertion, engages a screw hole positioned on a side surface of the drive 500. Engaging the disk drive 500 along two dimensions increases the carrier's 400 retention of the drive 500. In some embodiments, the peg 435a disposed on the back member 405 can be configured as a cross rib. The cross-sectional area of the peg 435a can be a cross. The length of the cross can equal the width of the cross.

The pegs are designed, for example, so that the drive can be manipulated to be releasably grabbed at the top by pegs 435a and 435b, while peg 435g and its opposed peg go in to corresponding screw holes on the side of the drive near the top. Similarly, while the pegs 435d and 435e provide an orientation for corresponding screw holes in the bottom back of the drive, the laterally oriented pegs 435d and 435f releasably grab the drive in screw holes disposed on the side of the drive and thus prevent for-aft motion of the lower portion of the drive.

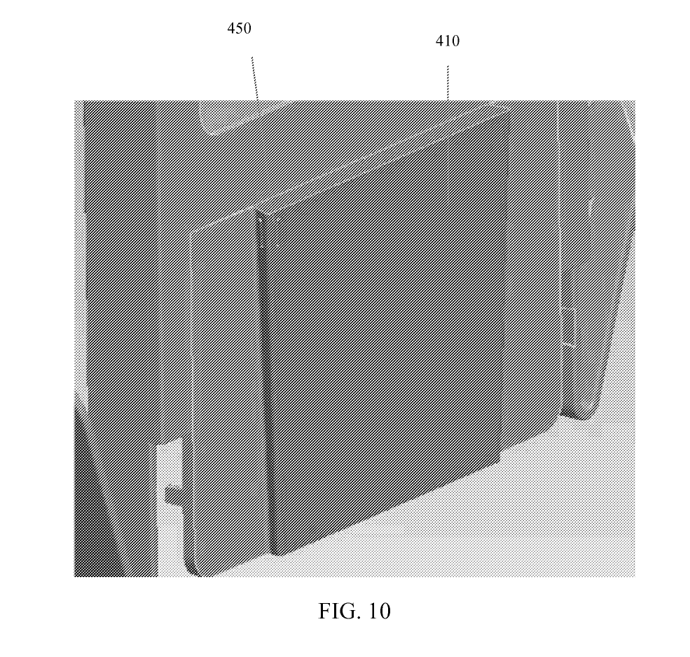

FIG. 10 shows a backside view of the carrier 400, including a portion 410 that protrudes from the outer surface of the carrier 400. In some embodiments, the portion 410 includes ridges 450 disposed near its top. The ridges 450 can be positioned such that their bottom ends are about 4.0 mm from the top of the portion 410. In some embodiments, ridges 450 can be disposed on the back of the portion 410. In some embodiments, ridges 450 can be disposed on the sides of the portion 410. When the disk drive carrier 400 is mounted in the base 300, the ridges 450 can guide the position of the carrier 400.

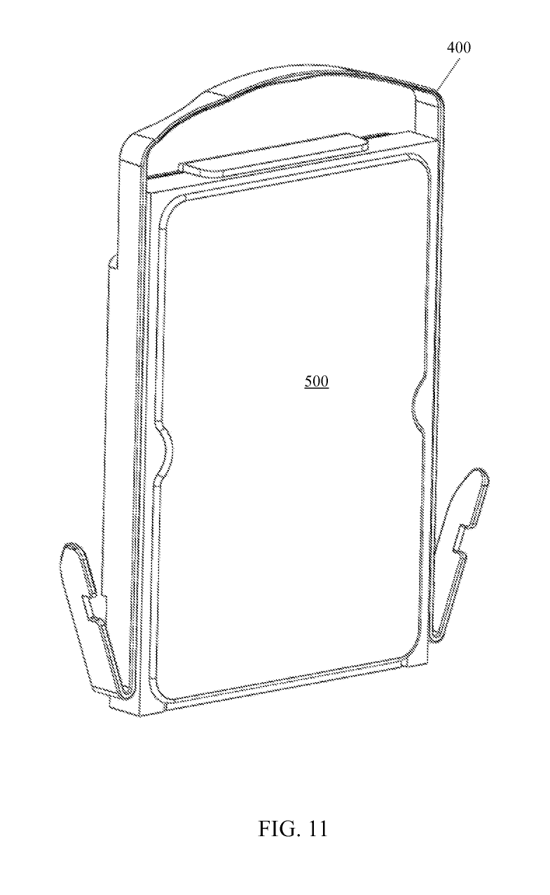

FIG. 11 shows a disk drive carrier 400 with a disk drive 500 mounted therein. The bottom of the disk drive 500 can extend beyond the bottom of the carrier 400.

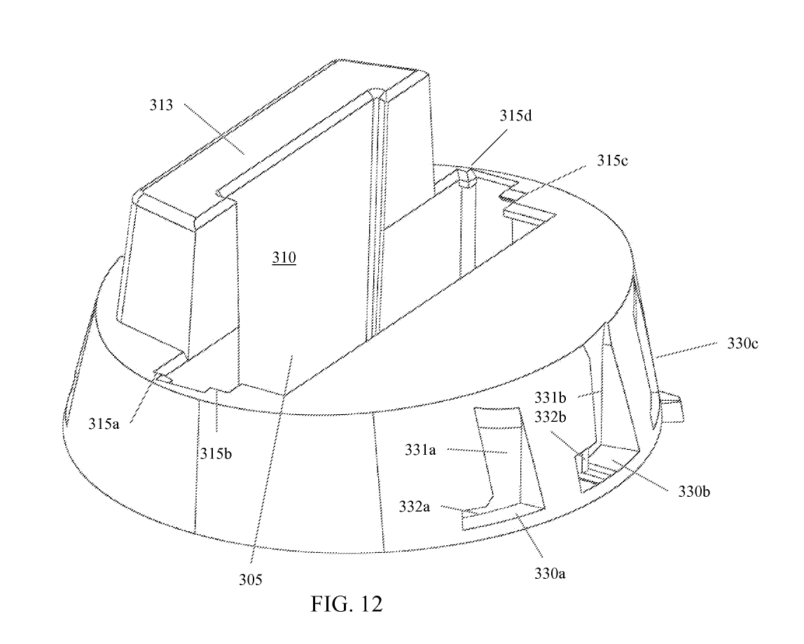

FIG. 12 shows a base 300. The base includes a recess 305 configured to receive a carrier 400 with a disk drive 500 mounted therein. The recess 305 can abut a socket 310 disposed within a stub 313. The socket 310 can be configured to receive the portion 410 of the carrier 400 that protrudes from the carrier's 400 outer surface. In some embodiments, as the carrier 400 is inserted into the recess 305, the portion 410 protruding from the carrier's 400 outer surface can slide into the socket 310 within the stub 313. The socket 310 can be configured to receive the portion 410 of the carrier. In some embodiments, the portion 410 can have a dove-tailed cross section and the socket 310 can be configured to receive the dove-tailed cross section of the portion 410 of the back member. The stub 313 can absorb mechanical stress from the printed circuit board (PCB) disposed in the disk drive 500. Additionally, the socket 310 and the stub 313 can guide a disk drive 500 to form a connection with the disk drive connector as the drive 500 is mounted in the base 300, as described herein.

The recess 305 can include protrusions 315a, 315b, 315c, 315d (collectively, “315”) configured to latch the carrier 400 to the base 300. The protrusions 315 can be disposed along opposing sides of the recess 305. In some embodiments, the recess 305 includes four protrusions 315, wherein two protrusions 315 can latch a notch 430 in a tang 425 of the carrier. The carrier 400 can be wider than the width of the recess 305, e.g., the distance between the two protrusions 315. Thus, if the carrier 400 is positioned over the recess 305, the bottom of the disk drive 500 does not contact the bottom surface of the recess 305 and the carrier 400 remains in a suspended position within the base 300.

To mount the carrier 400 in the base 300, a user moves the tangs 425 inward towards the disk drive and inserts the carrier 400 into the recess 305 until the notches 430 in the tangs 425 are proximate to the protrusions 315. In some embodiments, when the notches 430 are thus proximate, the bottom surface of the disk drive 500 contacts the bottom surface of the recess 305. When the user releases the tangs 425, the tangs 425 move outward such that the notches 430 in the tangs 425 engage with the protrusions 315. The engagement temporarily fixes the tangs 425 in biased positions, thereby mounting the carrier 400 in the base 300. In this state, the carrier 400 cannot be removed simply by pulling the carrier 400 by the spring 420 in a direction perpendicular to the base 300. To release the carrier 400 from the base 300, a user must move the tangs 425 inward towards the disk drive to disengage notches 430 in the tangs 425 from the protrusions 315. Then, a user can pull the carrier 400 in a direction perpendicular to the base 300 to remove the carrier 400.

In some embodiments, due to the width of the recess 305, the flexible tangs 425 remained biased towards the disk drive when its notches 430 are engaged with protrusions 315 in the base. Tension in the tangs 425 is propagated through the side members 415 such that the disk drive 500 mounted in the carrier 400 is further secured therein.

In some embodiments, a disk drive connector (not shown) is disposed on a bottom surface of the recess 305. The disk drive connector can include an interface that communicates with an interface of the disk drive 500 mounted into the carrier 400. The disk drive connector can include circuitry for detecting the presence of the disk drive 500. Various components of the carrier 400 and the base 300 are configured to orient a disk drive 500 that is mounted in the carrier 400 to form a connection with the disk drive connector. In some embodiments, the portion 410 of the carrier 400 that has a dove-tailed cross section and the socket 310 of the base 300 configured to receive the dove-tailed cross section of the portion 410 orient the disk drive 500 with respect to the disk drive connector. The portion 410 and the socket 310 guide the disk drive 500 to the disk drive connector. In some embodiments, the tangs 425 of the carrier 400 are configured to orient the disk drive 500, guiding the disk drive 500 to the connector. In some embodiments, the base 300 includes a shim (not shown) that orients the disk drive 500 with respect to the connector. Any of these components, alone or in combination, can be configured to guide a disk drive 500 of any form factor to form a connection with the connector when the disk drive 500 is mounted in the base 300.

In some embodiments, the disk drive connector can be positioned at a depth within the recess 305 such that the disk drive connector contacts the disk drive's 500 interface when the notches 430 of the tangs 425 engage with the protrusions 315. Thus, the disk drive connector detects a disk drive 500 when the carrier 400 is latched and thus mounted in the base 300. In some embodiments, upon detecting the disk drive 500, the base 300 illuminates a light (e.g., a light-emitting diode, or LED) to indicate that the carrier 400 is properly mounted. When a user removes the carrier 400, such removal breaks the connection between the disk drive 500 and the disk drive connector. The base 300 can cease to illuminate the light.

The base 300 can include grooves 330a, 330b, 330c (collectively “330”) configured to receive one or more teeth from a cover 200 to latch the cover 200 to the support 300. In this figure, only three grooves 330 are shown, although the base 300 can have a duplicate set of three grooves 330 on its opposite side or any number of grooves, as would be appreciated by one of ordinary skill in the art. Each groove 330 can include a main body 331 and a notch 332 abutting the main body 331 at a lower corner. The groove 330 can be configured to receive a tooth from the cover 200. The tooth can slide into the main body 331 from its top. When a user rotates the cover 200 in a clockwise direction, a portion of the tooth can rotate to enter the notch 332 from the main body 331. When such portions are inserted into the notches 332, the cover 200 is latched to the base 300.

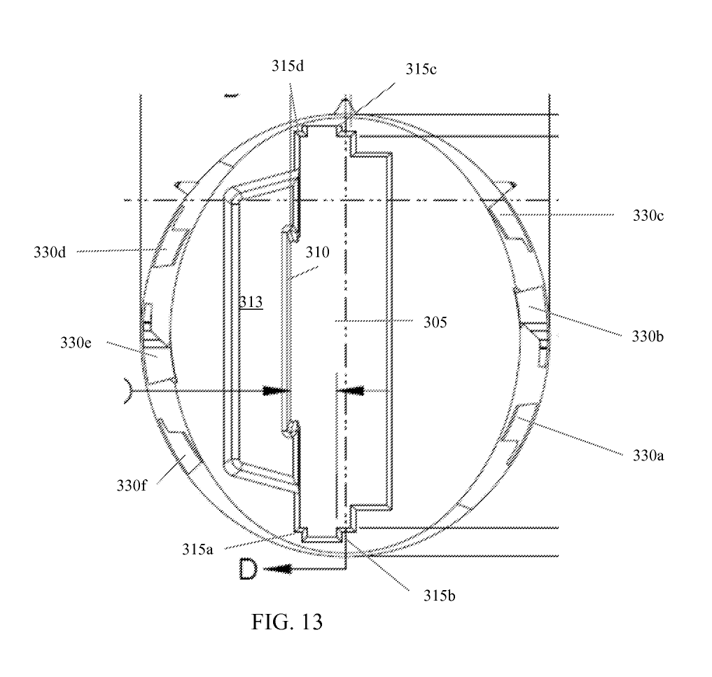

FIG. 13 shows an overhead perspective of the base 300. This perspective depicts the recess 305, the protrusions 315, and the stub 313 with a socket 310 configured to receive a portion 410 of the carrier 400 that protrudes from an outer surface of the carrier 400. The perspective also depicts six grooves 330 disposed along an outer perimeter of the base 300. Three grooves 330 are disposed along one side of the support 300, and the other three grooves are disposed along the opposite side.

The central groove 330 in each set of three has a different shape than the side grooves 330. In some embodiments, the central groove 330 is configured to receive a tooth from a cover 200 such that engaging the tooth latches the cover 200 to the base 300. In some embodiments, the side grooves 330 are configured to receive teeth from the cover 200 such that engaging the teeth stabilizes the connection between the cover 200 and the base 300.

In some embodiments, the distance between protrusions 315 on opposing sides of the recess 305 can be about 80.70 mm. In some embodiments, the socket 310 in the stub 313 can be about 9.54 mm deep.

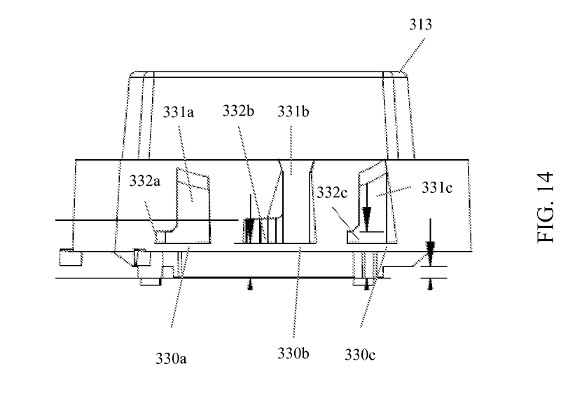

FIG. 14 shows a side perspective of the base 300. The side perspective depicts three of the grooves 330 disposed along the outer perimeter of the base. In this embodiment, the notch 332 of the central groove 330 includes a series of ridges. When the cover 200 is rotated, the rotation pushes a tooth in the cover 200 over the series of ridges. Because of the force needed to force the tooth over each ridge, a tooth disposed in the central groove's notch 332 can be resistant to disturbance (e.g., the tooth can remain in the notch 332 despite sudden trauma). In some embodiments, the notches 332 in the side grooves 330 can include smooth surfaces. In some embodiments, the side grooves 330 can have identical shapes.

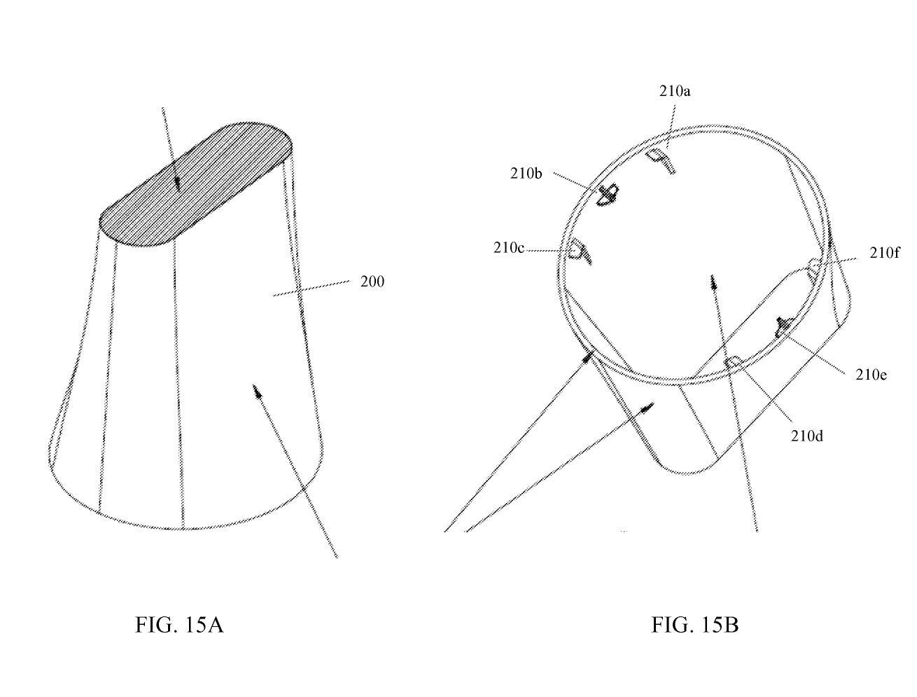

FIG. 15 shows top and bottom perspectives of a cover 200. The cover 200 can include a top, outer surface 205. The width of the top, outer surface 205 can be about 28.0 mm. In some embodiments, the top, outer surface 205 is textured. In some embodiments, the height of the cover 200 is about 110.00 mm. When a carrier 400 is mounted in the base 300 and the cover 200 is placed over the support 300, the height of the cover 200 can be less than the height of the carrier 400. The cover 200 is secured to the base by rotating the cover about a vertical axis, namely an axis that is perpendicular to the base. When the cover is thus rotated it assumes a latched position relative to the base, using teeth in the cover that are described below. When the cover 200 is in the latched position, a top, inner surface of the cover 200 engages against the carrier's spring 420, causing teeth of the cover to more firmly engage the base and thus assist in retaining the cover 200 in the latched position. The bottom perspective depicts the six teeth 210 disposed along an inner perimeter of the cover 105. The teeth 210 can be organized into groups of three teeth 210. The central tooth 210 in each group can have a different form factor than its side teeth 210. In some embodiments, the side teeth 210 have the same form factor. In some embodiments, the teeth 210 adjacent to the central tooth 210 have similar shapes, but their dimensions may differ.

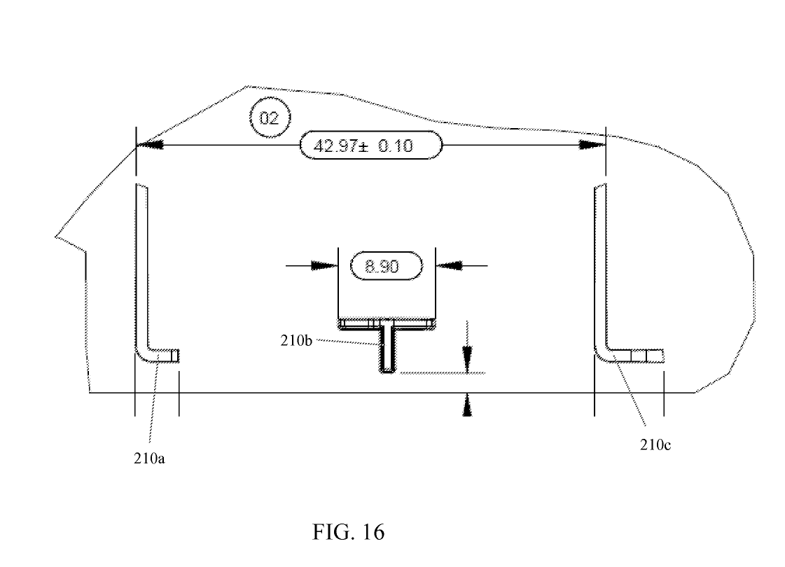

FIG. 16 shows a group of three teeth 210 disposed along an inner perimeter of the cover 105. The central tooth 210 can have a cross-sectional area in the form of a T. In some embodiments, the width of the central tooth 210 is about 8.90 mm. The height of the central tooth 210 can be about 4.86 mm. In some embodiments, the central tooth 210 can be positioned about 1.84 mm from the bottom of the cover 105. In some embodiments, each side tooth 210 includes a vertical rod and a horizontal rod, wherein the rods are disposed at substantially 90° to one another. The distance between the vertical rods of the side teeth 210 can be about 42.97 mm. The horizontal rods can be positioned about 3.9 mm from the bottom of the cover 200. In some embodiments, the length of a horizontal rod can be about 3.96 mm. In some embodiments, the length of a horizontal rod can be about 6.35 mm. Although the horizontal rods shown in FIG. 16 have different lengths, in some embodiments, the horizontal rods of side teeth 210 can have the same lengths.

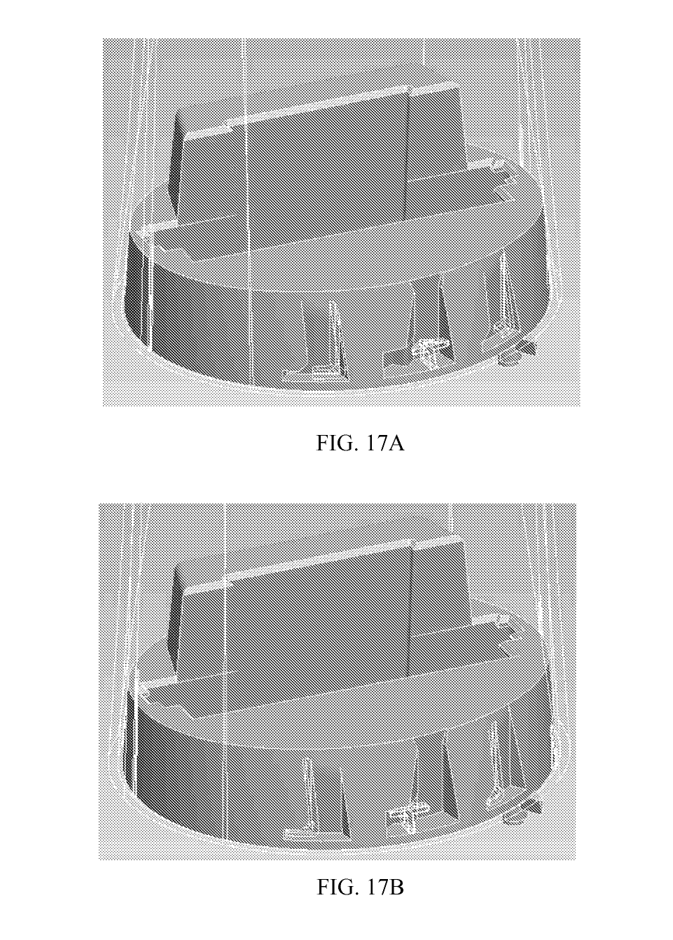

FIG. 17 shows the cover in unlatched and latched positions relative to the base. The white lines correspond to the outline of the cover's features. When the cover 200 is placed over the base 300, the teeth 210 slide vertically into the main bodies 331 of the grooves 330. When the cover is rotated, the teeth 210 slide horizontally into notches 332 abutting the main bodies 331. From this position, the teeth 210 cannot be extracted from the grooves 330 by pulling the cover 105 in a vertical direction. The cover 105 must be rotated counter-clockwise to disengage the teeth 210 from the notches 332 before the cover 105 can be removed.

Various embodiments of the present invention may be characterized by the potential claims listed in the paragraphs following this paragraph (and before the actual claims provided at the end of this application). These potential claims form a part of the written description of this application. Accordingly, subject matter of the following potential claims may be presented as actual claims in later proceedings involving this application or any application claiming priority based on this application. Inclusion of such potential claims should not be construed to mean that the actual claims do not cover the subject matter of the potential claims. Thus, a decision to not present these potential claims in later proceedings should not be construed as a donation of the subject matter to the public.

The embodiments of the invention described above are intended to be merely exemplary; numerous variations and modifications will be apparent to those skilled in the art. All such variations and modifications are intended to be within the scope of the present invention as defined in any appended claims.

What is claimed is:

1. A carrier for a disk drive, comprising:
a back member configured to abut a face of the disk drive;
a pair of side members coupled to the back member, configured to abut opposing sides of the disk drive; and
a pair of flexible tangs, each tang coupled to one of the side members and configured to removably mount the carrier in a base; and
wherein the back member is, or the side members are, or the back member and side members are, configured with a set of attachment mechanisms in locations that correspond to locations, in the disk drive, of screw holes used for mounting so that the disk drive is removably mountable in the carrier using the attachment mechanisms and an assembly of the carrier with the disk drive is removably mountable in the base.

2. A carrier according to claim 1, wherein the attachment mechanisms are screws, placed through holes in the back member, or in the side members, or in the back member and the side members, as the case may be, that are removably insertable into corresponding screw holes in the disk drive.

3. A carrier according to claim 1, wherein the attachment mechanisms are pegs, mounted on the back member, or on the side members, or on the back member and the side members, as the case may be, that are removably insertable into corresponding screw holes in the disk drive.

4. A carrier according to claim 1, wherein a portion of the back member is configured to engage with a corresponding portion of the base.

5. A carrier according to claim 4, wherein the portion of the back member has a dove-tailed cross section and the portion of the base is configured to receive the dove-tailed cross section of the portion of the back member when the latter is slid into the former.

6. A carrier according to claim 1, wherein each of the tangs is configured for releasably latching the carrier in a base.

7. A carrier according to claim 1, wherein the set of pegs of the back member includes a set of nibs and a set of pegs, wherein each nib is smaller than each peg.

8. A carrier according to claim 1, wherein the set of pegs of each side member includes a set of nibs and a set of pegs, wherein each nib is smaller than each peg.

9. A carrier according to claim 1, wherein each tang has a notch configured to engage with a corresponding protrusion in the base, so that the tang can be moved inwardly toward the disk drive to release the protrusion from engagement with the notch and wherein the tang is biased in a position wherein the protrusion is normally engaged in the notch.

10. A carrier according to claim 1, wherein the carrier is configured to accommodate a disk drive between 7.0 mm and 15.0 mm in thickness.

11. A carrier according to claim 3, wherein all components thereof are integrally formed from a single piece of material.

12. A carrier according to claim 11, wherein all components are plastic and formed in a mold.

13. A carrier according to claim 12, further comprising:
a flexible spring that connects the pair of side members, wherein the spring is configured to transfer pressure applied to the spring to the side members.

14. An assembly, for a digital storage appliance, comprising:
a base comprising a recess with protrusions configured to latch a module that is removably insertable in the base;
a disk drive carrier having
a back member configured to abut a face of the disk drive;
a pair of side members coupled to the back member, configured to abut opposing sides of the disk drive; and
a pair of flexible tangs, each tang coupled to one of the side members and configured to removably latch with one of the protrusions in the base so as to removably mount the carrier in the base;
wherein the back member is, or the side members are, or the back member and side members are, configured with a set of attachment mechanisms in locations that correspond to locations, in the disk drive, of screw holes used for mounting so that the disk drive is removably mountable in the carrier using the attachment mechanisms and the module, constituting the carrier with the disk drive, is removably mountable in the base; and
a cover configured to mate with the base to enclose the mounted disk drive carrier.

15. An assembly according to claim 14, wherein the protrusions of the base are disposed along opposing sides of the recess.

16. An assembly according to claim 14, wherein a stub of the base comprises a socket with a dove-tailed cross section configured to receive an inserted portion of the back member of the disk drive carrier.

17. An assembly according to claim 12, wherein the base further comprises circuitry disposed in the recess that detects a presence of the module, constituting the carrier with the disk drive, inserted into the recess.

18. An assembly according to claim 12, wherein the protrusions are configured to move the latched tangs inward towards the disk drive, thereby further securing a disk drive mounted into the disk drive carrier.

19. An assembly according to claim 12, wherein a height of the disk drive carrier mounted in the base is greater than a height of the cover when mated with the base such that a top inner surface of the cover depresses a spring disposed at the top of the disk drive carrier, thereby further securing the disk drive carrier within the base.

20. An assembly according to of claim 12, wherein the base comprises a first plurality of grooves disposed along an outer perimeter and the cover comprises a first plurality of teeth disposed along an inner perimeter, such that the cover mates with the base by latching the first plurality of teeth with the first plurality of grooves.

21. An assembly according to claim 17, wherein the first plurality of teeth latches with the first plurality of grooves to lock the position of the cover relative to the base.

22. An assembly according to claim 18, wherein the base comprises a second plurality of grooves disposed along the outer perimeter and the cover comprises a second plurality of teeth disposed along the inner perimeter, and wherein the second plurality of teeth latches with the second plurality of grooves to stabilize the position of the cover relative to the base.

23. An assembly, for a digital storage appliance, comprising:
a base comprising a recess to receive a module that is removably insertable in the base;
a disk drive carrier having
a back member configured to abut a face of the disk drive;
a pair of side members coupled to the back member, configured to abut opposing sides of the disk drive;
wherein the back member is, or the side members are, or the back member and side members are, configured with a set of attachment mechanisms in locations that correspond to locations, in the disk drive, of screw holes used for mounting so that the disk drive is removably mountable in the carrier using the attachment mechanisms and the module, constituting the carrier with the disk drive, is removably mountable in the base;
a spring mounted on the disk drive carrier, the spring exposed above the disk drive when the module is mounted in the base; and
a cover, configured to mate with the base and, when rotated about a vertical axis, to assume a latched position with respect to the base, the cover also configured when mated to the base to enclose the mounted disk drive carrier, the cover having an inner top surface, and, when the carrier is in the latched position, the spring engages against the inner top surface of the cover and applies a force tending to urge the cover upward and away from the base in a manner to assist in maintaining the latched position.

24. An assembly according to claim 23, wherein the spring is implemented by an arcuate flexible band linking the pair of side members of the carrier.
